(19) United States
(12) Patent Application Publication
(10) Pub. No.: US 2025/0081404 A1
(43) Pub. Date: Mar. 6, 2025

(54) SERVER SYSTEM AND HEAT DISSIPATION MODULE

(71) Applicant: Wiwynn Corporation, New Taipei City (TW)

(72) Inventors: Zi-Ping Wu, New Taipei City (TW); Tsung-Han Li, New Taipei City (TW); TING YU PAI, New Taipei City (TW); NENG CHIEH CHANG, New Taipei City (TW)

(21) Appl. No.: 18/403,856

(22) Filed: Jan. 4, 2024

(30) Foreign Application Priority Data
Sep. 5, 2023 (TW) 112133663

(51) Int. Cl. H05K 7/20

(52) U.S. Cl. CPC H05K 7/20781; H05K 7/20272

(57) ABSTRACT

A server system includes a rack, servers disposed in the rack and a heat dissipation module including a pump assembly, a main manifold assembly, heat exchange assemblies and a sub manifold assembly. The pump assembly is disposed in the rack. The main manifold assembly includes two main pipelines, one is connected to a main outlet of the pump assembly and inlets of the servers, and the other is connected to outlets of the servers and a main inlet of the pump assembly. The heat exchange assemblies are removably disposed in the rack. The sub manifold assembly includes two sub pipelines, one is connected to a sub outlet of the pump assembly and inlets of the heat exchange assemblies, and the other is connected to outlets of the heat exchange assemblies and a sub inlet of the pump assembly.

### CROSS-REFERENCE TO RELATED APPLICATIONS

This non-provisional application claims priority under 35 U.S.C. § 119 (a) on Patent Application No(s). 112133663 filed in Taiwan, R.O.C. on Sep. 5, 2023, the entire contents of which are hereby incorporated by reference.

### TECHNICAL FIELD

The disclosure relates to a server system and a heat dissipation module.

### BACKGROUND

In general, servers in a server rack are mostly cooled by a liquid cooling heat dissipation module. There are three types of arrangements of the liquid cooling heat dissipation module. One is to arrange the liquid cooling heat dissipation module in a separate rack, another is to arrange the liquid cooling heat dissipation module at a rear door of the server rack, and the other is to arrange the liquid cooling heat dissipation module inside the server rack.

Regarding the type of arranging the liquid cooling heat dissipation module in a separate rack, the liquid cooling heat dissipation module and the servers are located in two different racks, and thus pipes for connecting the liquid cooling heat dissipation module and the servers cannot be installed in advance until both racks are positioned in the predetermined positions within a server room. Otherwise, the two racks are difficult to be moved to predetermined positions. In addition, these two racks are required to be used as one set, and thus when a remaining space of the server room is only capable of accommodating one rack, these two racks are difficult to be placed in the remaining space of the server room simultaneously, resulting in unused space and inefficient utilization of the server room.

Regarding the type of arranging the liquid cooling heat dissipation module at a rear door of the server rack, not only the rear door and the liquid cooling heat dissipation module may increase the overall space required, but also maintenance personnel is required to be exposed to a higher ambient temperature behind the rack during maintenance, which does not meet safety regulations.

As for the type of arranging the liquid cooling heat dissipation module inside the server rack, the liquid cooling heat dissipation module includes a set of pumps, a heat exchanger and a set of fans integrated in the server rack. However, the cooling capacity of the heat exchanger is constant and unable to be adjusted, which cause the heat exchanger to be insufficient to cool more servers, thereby affecting the quantity of servers that can be accommodated in the server rack.

### SUMMARY

One embodiment of the disclosure provides a server system. The server system includes a rack, a plurality of servers and a heat dissipation module. The servers are disposed in the rack and each has an inlet and an outlet. The heat dissipation module includes a pump assembly, a main manifold assembly, a plurality of heat exchange assemblies and a sub manifold assembly. The pump assembly is disposed in the rack and has a main inlet, a sub inlet, a main outlet and a sub outlet. The main manifold assembly includes a first main pipeline and a second main pipeline. The first main pipeline is connected to the main outlet of the pump assembly and the inlet of each of the servers, and the second main pipeline is connected to the outlet of each of the servers and the main inlet of the pump assembly. The heat exchange assemblies are removably disposed in the rack and each has an inlet and an outlet. The sub manifold assembly includes a first sub pipeline and a second sub pipeline. The first sub pipeline is connected to the sub outlet of the pump assembly and the inlet of each of the heat exchange assemblies, and the second sub pipeline is connected to the outlet of each of the heat exchange assemblies and the sub inlet of the pump assembly.

Another embodiment of the disclosure provides a heat dissipation module. The heat dissipation module includes a pump assembly, a plurality of heat exchange assemblies and a sub manifold assembly. The pump assembly has a sub inlet and a sub outlet. The heat exchange assemblies each has an inlet and an outlet. The sub manifold assembly includes a first sub pipeline and a second sub pipeline. The first sub pipeline is connected to the sub outlet of the pump assembly and the inlet of each of the heat exchange assemblies, and the second sub pipeline is connected to the outlet of each of the heat exchange assemblies and the sub inlet of the pump assembly.

Still another embodiment of the disclosure provides a server system. The server system includes a rack, a plurality of servers and a heat dissipation module. The rack has an accommodation space and an inner bottom surface located at a bottom of the accommodation space. The servers are disposed in the accommodation space. The heat dissipation module includes a pump assembly and a plurality of heat exchange assemblies. The pump assembly is disposed in the accommodation space and communicate with the servers. The heat exchange assemblies are removably disposed in the accommodation space and communicate with the pump assembly. Heights of the servers, the pump assembly and the heat exchange assemblies relative to the inner bottom surface are different from one another.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a server system according to one embodiment of the disclosure;

FIG. 2 is another perspective view of the server system in FIG. 1;

FIG. 3 is a partially enlarged front view of the server system in FIG. 1;

FIG. 4 is a schematic view of the server system in FIG. 1;

FIG. 5 is a perspective view of a pump assembly of the server system in FIG. 1;

FIG. 6 is a perspective view of a heat exchange assembly of the server system in FIG. 1; and

FIG. 7 is another perspective view of the heat exchange assembly of the server system in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

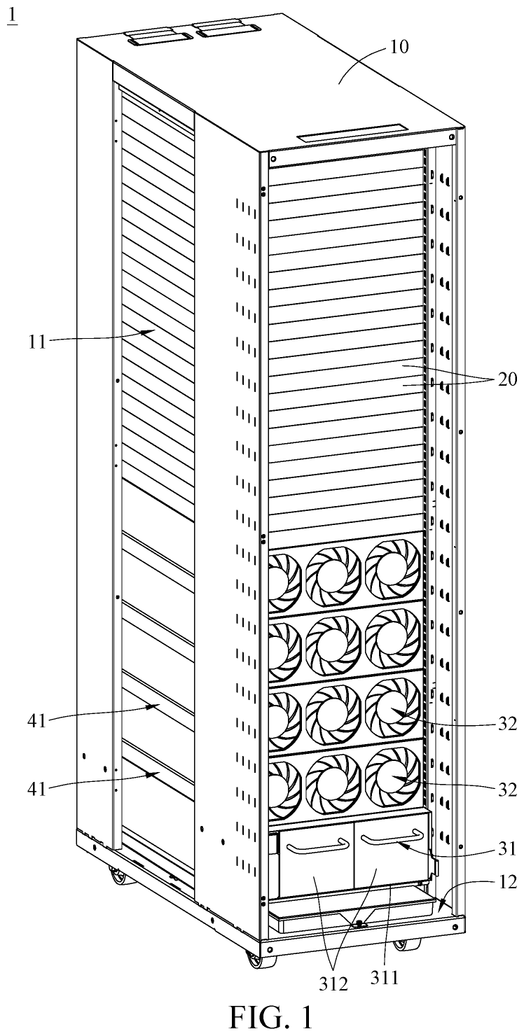

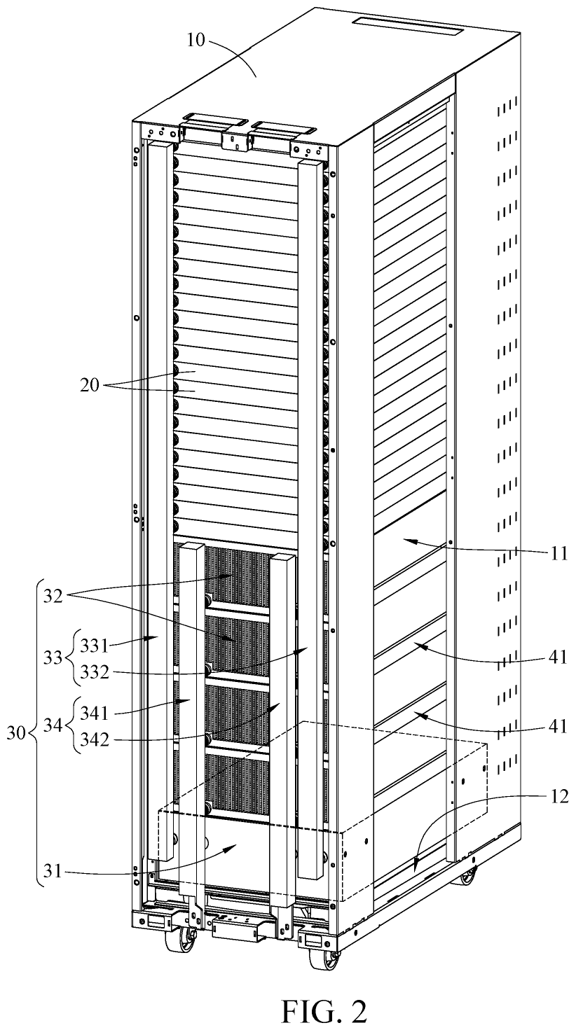

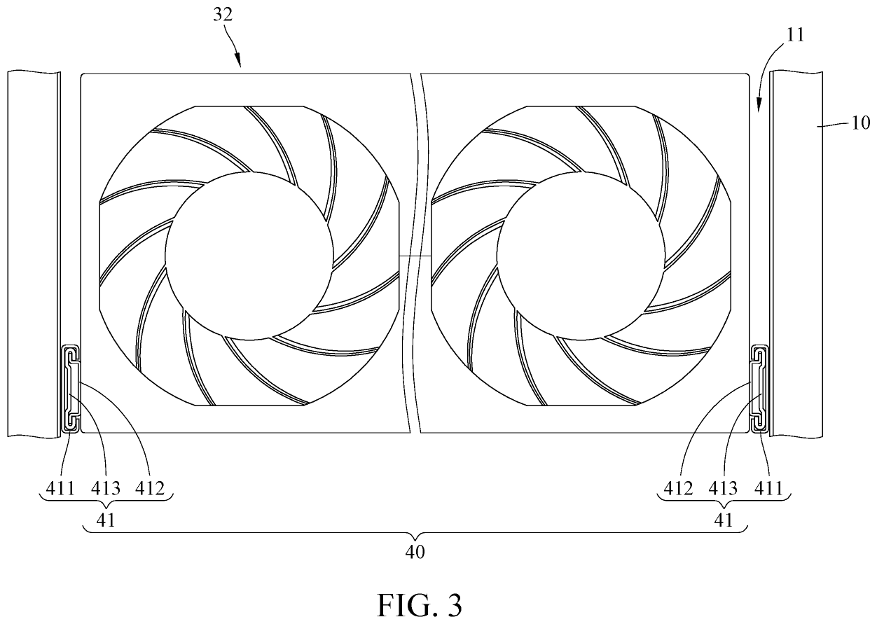

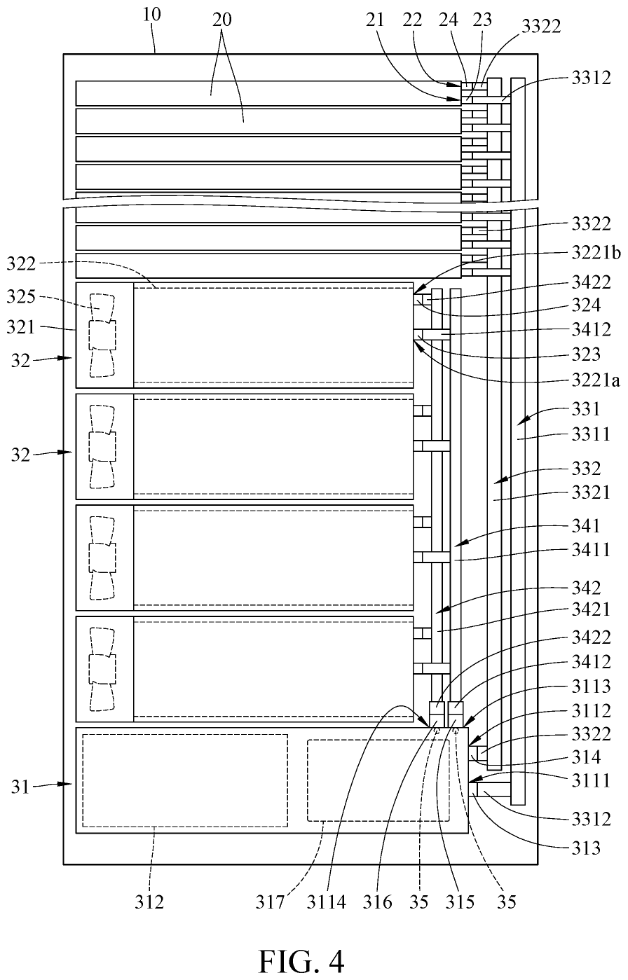

Referring to FIGS. 1 to 4, FIG. 1 is a perspective view of a server system 1 according to one embodiment of the disclosure, FIG. 2 is another perspective view of the server system 1 in FIG. 1, FIG. 3 is a partially enlarged front view of the server system 1 in FIG. 1, and FIG. 4 is a schematic view of the server system 1 in FIG. 1.

In this embodiment, the server system 1 includes a rack 10, a plurality of servers and a heat dissipation module 30. In addition, the server system 1 further includes a plurality of rail assemblies 40. The heat dissipation module 30 includes a pump assembly 31, a plurality of heat exchange assemblies 32, a main manifold assembly 33 and a sub manifold assembly 34.

The rack 10 has an accommodation space 11 and an inner bottom surface 12. The inner bottom surface 12 of the rack 10 is located at a bottom of the accommodation space 11. The servers 20, the pump assembly 31 and the heat exchange assemblies 32 are located in the accommodation space 11, and heights of the servers 20, the pump assembly 31 and the heat exchange assemblies 32 relative to the inner bottom surface 12 are different from one another. For example, the heat exchange assemblies 32 are located between the servers 20 and the pump assembly 31, and the pump assembly 31 is located closer to the inner bottom surface 12 than the heat exchange assemblies 32 and the servers 20. In other words, the heat exchange assemblies 32 are located above the pump assembly 31, and the servers 20 are located above the heat exchange assemblies 32. Note that the relative positions among the pump assembly 31, the heat exchange assemblies 32 and the servers 20 are not restricted in the disclosure and may be modified according to actual requirements.

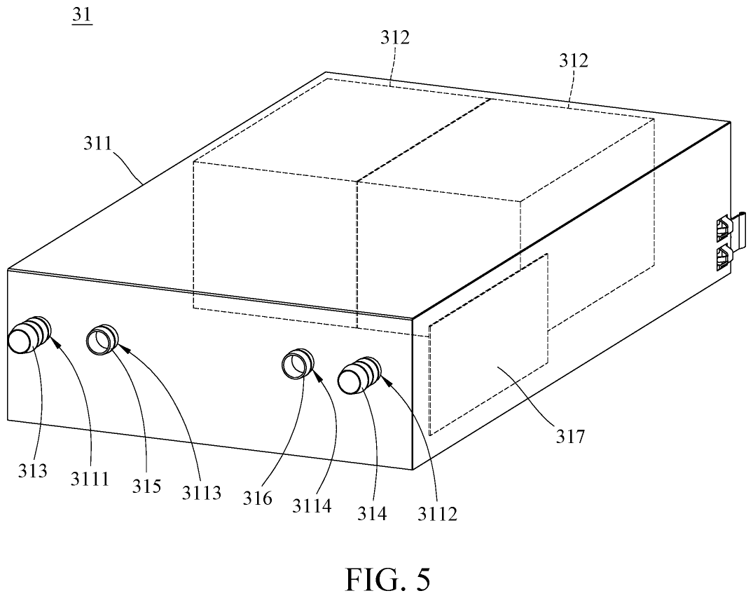

Then, referring to FIGS. 4 and 5, FIG. 5 is a perspective view of the pump assembly 31 of the server system 1 in FIG. 1

In this embodiment, the servers 20 are, for example but not limited to, 1 U servers 20. Each of the servers 20 has an inlet 21, an outlet 22 and two joints 23 and 24 which are respectively disposed at the inlet 21 and the outlet 22.

The pump assembly 31 includes a casing 311, two pump units 312, two main joints 313 and 314, two sub joints 315 and 316 and a controller 317. The casing 311 has a main outlet 3111, a main inlet 3112, a sub outlet 3113 and a sub inlet 3114. The pump units 312 are removably disposed in the casing 311, and the pump units 312 are in parallel fluid communication with the main outlet 3111, the main inlet 3112, the sub outlet 3113 and the sub inlet 3114 via pipes (not shown). The main joints 313 and 314 are respectively disposed at the main outlet 3111 and the main inlet 3112, and the sub joints 315 and 316 are respectively disposed at the sub outlet 3113 and the sub inlet 3114. The controller 317 is, for example, electrically connected to the pump units 312.

As shown in FIG. 5, the main outlet 3111, the main inlet 3112, the sub outlet 3113 and the sub inlet 3114 are located at the same side of the casing 311, but the disclosure is not limited thereto, and the positions of the main outlet, the main inlet, the sub outlet and the sub inlet may be modified according to actual requirements. For example, the main outlet and the main inlet may be located at one side of the casing, and the sub outlet and the sub inlet may be located at another side of the casing.

In this embodiment, one of the pump units 312 of the pump assembly 31 serves as a primary pump unit 312 responsible for driving a working fluid, while the other one of the pump units 312 serves as a spare pump unit 312. When the controller 317 detects the primary pump unit 312 is in malfunction, the controller 317 enables the spare pump unit 312 to drive the working fluid.

Note that the quantity of the pump units 312 are not restricted in the disclosure and may be modified according to actual requirements.

The main manifold assembly 33 includes a first main pipeline 331 and a second main pipeline 332. The first main pipeline 331 includes a first main pipe 3311 and a plurality of first main joints 3312, and the first main joints 3312 are disposed on the first main pipe 3311. The first main joints 3312 of the first main pipeline 331 are respectively assembled with the joints 23 of the servers 20 and the main joint 313 of the pump assembly 31, such that the main outlet 3111 of the pump assembly 31 is connected to the inlets 21 of the servers via the first main pipeline 331. The second main pipeline 332 includes a second main pipe 3321 and a plurality of second main joints 3322. The second main joints 3322 are disposed on the second main pipe 3321. The second main joints 3322 of the second main pipeline 332 are respectively assembled with the joints 24 of the servers 20 and the main joint 314 of the pump assembly 31, such that the main inlet 3112 of the pump assembly 31 is connected to the outlets 22 of the servers 20 via the second main pipeline 332.

In this embodiment, the main joints 313 and 314 of the pump assembly 31, the first main joints 3312 of the first main pipeline 331, the joints 23 and 24 of the servers 20 and the second main joints 3322 of the second main pipeline 332 are toolless quick release joints for facilitating the efficiency of installation and removal thereof.

Note that the first main pipe 3311 of the first main pipeline 331 is not restricted to being connected to the inlets 21 of the servers 20 and the main outlet 3111 of the pump assembly 31 via the joints, and the second main pipe 3321 of the second main pipeline 332 is not restricted to being connected to the outlets 22 of the servers 20 and the main inlet 3112 of the pump assembly 31 via the joints. In some other embodiments, the first main pipe of the first main pipeline may be directly connected to the inlets of the servers and the main outlet of the pump assembly, and the second main pipe of the second main pipeline may be directly connected to the outlets of the servers and the main inlet of the pump assembly; that is, each of the servers may not have the joints, the pump assembly may not have the main joints, the first main pipeline may not have the first main joints, and the second main pipeline may not have the second main joints.

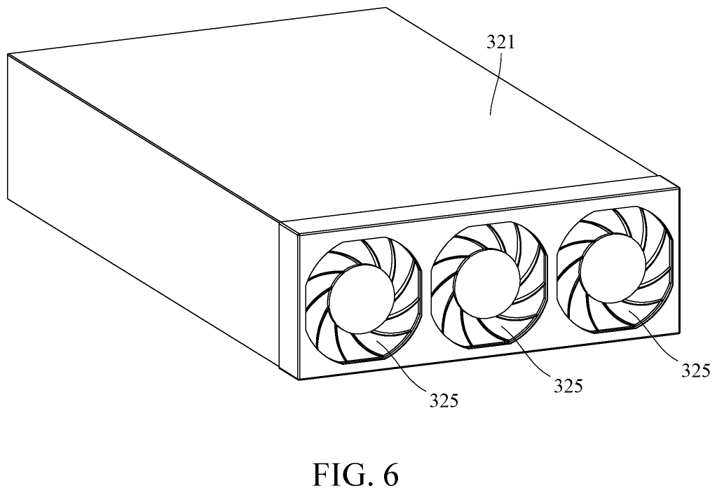

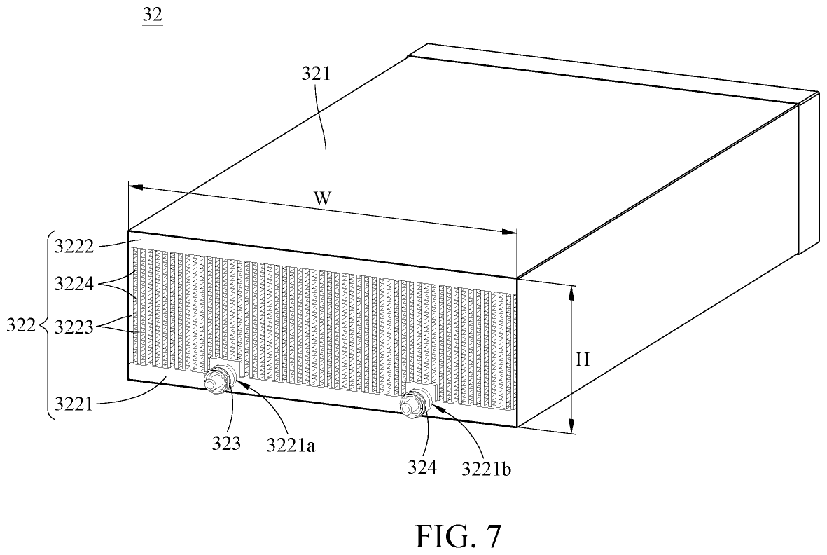

Then, referring to FIGS. 4, 6 and 7, FIG. 6 is a perspective view of the heat exchange assembly 32 of the server system 1 in FIG. 1, and FIG. 7 is another perspective view of the heat exchange assembly 32 of the server system 1 in FIG. 1.

In this embodiment, each of the heat exchange assemblies 32 is, for example, removably disposed in the accommodation space 11 of the rack 10 via one rail assembly 40. For example, this rail assembly 40 includes two rails 41. The rails 41 are, for example but not limited to, three-piece rails. Each rail 41 includes a first part 411, a second part 412 and a third part 413. The first parts 411 of the two rails 41 are respectively fixed to two opposite sides of the rack 10. The second parts 412 of the two rails 41 are respectively fixed to two opposite sides of the heat exchange assembly 32, and the second parts 412 of the two rails 41 are slidably disposed on the first parts 411 via the third parts 413, respectively, such that the heat exchange assembly 32 is removably disposed in the accommodation space 11 of the rack 10.

Note that each of the heat exchange assemblies 32 is not restricted to removably disposed in the accommodation space 11 of the rack 10 via the rail assemblies 40. In some other embodiments, the server system may not include the rail assemblies, but may include a plurality of supports. These supports may be L-shaped brackets, and the supports may be disposed at two opposite sides of the accommodation space of the rack so as to form a plurality of installation slide slots for guiding the installations or removals of the heat exchange assemblies. After the heat exchange assemblies are mounted into the installation slide slots, the heat exchange assemblies are fixed to the supports via fasteners (e.g., screws, such as thumb screws) or snap-fit mechanisms which can be operated by hands.

In the illustrated embodiment, the heat exchange assemblies 32 are the same in structure, and thus only one of them will be described in detail hereinafter. The heat exchange assembly 32 includes a casing 321, a heat exchanger 322, two joints 323 and 324 and a plurality of fans 325. The heat exchanger 322 is located in the casing 321. The heat exchanger 322 is, for example, a radiator and may include a bottom plate 3221, a top plate 3222, a plurality of connection plates 3223 and a plurality of fin structures 3224. The bottom plate 3221 is connected to the top plate 3222 via the connection plates 3223, and the bottom plate 3221, the top plate 3222 and the connection plates 3223 are thermally coupled to one another. The bottom plate 3221, the top plate 3222 and the connection plates 3223 are provided with channel structures (not shown) therein. The fin structures 3224 are located between any adjacent two of the connection plates 3223, and the fin structures 3224 are thermally coupled to the connection plates 3223. A width W of the heat exchanger 322 is about 530 mm, and a height H of the heat exchanger 322 is substantially equal to a height of a 4 U server, where 4 U may represent 4 rack units (i.e., RU) or 4 open rack units (i.e., OU). The bottom plate 3221 has an inlet 3221a and an outlet 3221b which are located at one side of the heat exchanger 322. The joints 323 and 324 are respectively disposed at the inlet 3221a and the outlet 3221b. The fans 325 are located in the casing 321 and are located at another side of the heat exchanger 322 located opposite to the inlet 3221a and the outlet 3221b.

Note that the size of the heat exchanger 322 is not restricted in the disclosure and may be modified according to actual requirements. For example, a width of the heat exchanger may be modified according a width of the rack, and the height of the heat exchanger may be greater or smaller than the height of the 4 U server. If the heat exchanger having a smaller height can provide a sufficient heat dissipation performance, this heat exchanger with the smaller height can be adopted to occupy less space in the rack, allowing for the accommodation of more servers in the rack.

Note that the structure of the heat exchanger 322 described above is merely exemplary and is not limited in the disclosure. The structure of the heat exchanger may be modified according to actual requirements.

The sub manifold assembly 34 includes a first sub pipeline 341 and a second sub pipeline 342. The first sub pipeline 341 includes a first sub pipe 3411 and a plurality of first sub joints 3412 disposed on the first sub pipe 3411. The first sub joints 3412 of the first sub pipeline 341 are respectively assembled with the joints 323 of the heat exchangers 322 and the sub joint 315 of the pump assembly 31, such that the sub outlet 3113 of the pump assembly 31 is connected to the inlets 3221a of the heat exchangers 322 via the first sub pipeline 341. The second sub pipeline 342 includes a second sub pipe 3421 and a plurality of second sub joints 3422 disposed on the second sub pipe 3421. The second sub joints 3422 of the second sub pipeline 342 are respectively assembled with the joints 324 of the heat exchangers 322 and the sub joint 316 of the pump assembly 31, such that the sub inlet 3114 of the pump assembly 31 is connected to the outlets 3221b of the heat exchangers 322 via the second sub pipeline 342.

In this embodiment, the sub joints 315 and 316 of the pump assembly 31, the first sub joints 3412 of the first sub pipeline 341, the joints 323 and 324 of the heat exchangers 322 and the second sub joints 3422 of the second sub pipeline 342 are toolless quick release joints for facilitating the efficiency of installation and removal thereof.

Note that the first sub pipe 3411 of the first sub pipeline 341 is not restricted to being connected to the inlets 3221a of the heat exchangers 322 and the sub outlet 3113 of the pump assembly 31 via the joints, and the second sub pipe 3421 of the second sub pipeline 342 is not restricted to being connected to the outlets 3221b of the heat exchangers 322 and the sub inlet 3114 of the pump assembly 31 via the joints. In some other embodiments, the first sub pipe of the first sub pipeline may be directly connected to the inlets of the heat exchangers and the sub outlet of the pump assembly, and the second sub pipe of the second sub pipeline may be directly connected to the outlets of the heat exchangers and the sub inlet of the pump assembly; that is, each of the heat exchangers may not have the joints, the pump assembly may not have the sub joints, the first sub pipeline may not have the first sub joints, and the second sub pipeline may not have the second sub joints.

Then, the operation of the server system 1 will be described hereinafter. As shown in FIG. 4, when the primary pump unit 312 of the pump assembly 31 is in operation, the primary pump unit 312 drives the working fluid to flow out of the pump assembly 31, and then the working fluid flows into the servers 20 via the first main pipeline 331 for absorbing heat generated by the servers 20. Then, the working fluid absorbing heat generated by the servers 20 flows out of the servers 20, and then flows back to the pump assembly 31 via the second main pipeline 332. Then, the primary pump unit 312 of the pump assembly 31 drives the working fluid to flow out of the pump assembly 31 again, and then the working fluid flows into the heat exchangers 322 via the first sub pipeline 341 for conducting heat absorbed by the working fluid to the heat exchangers 322, thereby cooling the working fluid. At this moment, during the operations of the fans 325, heat absorbed by the heat exchangers 322 is dissipated by a forced convection manner. Then, the cooled working fluid flows out of the heat exchangers 322 and then returns to the pump assembly 31 via the second sub pipeline 342. As a result, the primary pump unit 312 constantly drives the working fluid to repeat the aforementioned loop, which enables the servers 20 to operate in appropriate temperatures.

In one case, a liquid cooling heat dissipation module and servers are disposed in two different racks, and thus pipes for connecting the liquid cooling heat dissipation module and the servers cannot be pre-installed before both racks are positioned in the predetermined positions within a server room. However, in this embodiment, the servers 20, the heat exchange assemblies 32 and the pump assembly 31 are accommodated in the same rack 10, which enables pipes for connecting with the servers 20, the heat exchange assemblies 32 and the pump assembly 31 to be pre-installed before the server system 1 is moved to a predetermined position of the server room. As a result, after the server system 1 is placed in the predetermined position of the server room, there is no need to assign maintenance personnel to connect those pipes with the servers 20, the heat exchange assemblies 32 and the pump assembly 31, thereby saving the arrangement of manpower. In addition, the heat exchange assemblies 32, the pump assembly 31 and the servers 20 are accommodated in the same rack 10, which facilitates the server system 1 to be placed in a confined space of the server room, thereby improving space utilization in the server room.

Furthermore, the heat exchange assemblies 32 and the pump assembly 31 are accommodated in the rack 10 instead of a rear side of the rack 10, which prevents the space occupied by the server system 1 from increasing, and prevents maintenance personnel from maintaining the server system 1 at the rear side of the rack 10 having a higher ambient temperature.

On the other hand, the heat exchange assemblies 32 are modularized and removable, and thus the quantity of the heat exchange assemblies 32 can be flexibly modified according to the heat dissipation requirement of the servers 20 in the rack 10. For example, assuming that the heat dissipation requirement of the servers 20 in the rack 10 is 40 KW, and each of the aforementioned heat exchange assemblies 32 can provide the cooling capability of 10 KW, a user can arrange four heat exchange assemblies 32 in the rack 10 for satisfying the heat dissipation requirement of the servers 20. Similarly, when the heat dissipation requirement of the servers 20 in the rack 10 is 30 KW, and each of the aforementioned heat exchange assemblies 32 can provide the cooling capability of 10 KW, the user can arrange three heat exchange assemblies 32 in the rack 10 for satisfying the heat dissipation requirement of the servers 20. Accordingly, compared to a case that a liquid cooling heat dissipation module includes a set of pumps, a heat exchanger and a set of fans integrated in a server rack (e.g., in one casing), and the cooling capacity of the heat exchanger is constant and unable to be adjusted, the heat exchange assemblies 32 are modularized and removable in this embodiment, which can prevent the cooling capability of the heat exchange assemblies 32 from being insufficient to the heat dissipation requirement of the servers 20, or from overly exceeding the heat dissipation requirement of the servers 20 to waste energy.

In this embodiment, the pump assembly 31 is in parallel communication with the heat exchangers 322 of the heat exchange assemblies 32, but the disclosure is not limited thereto; in some other embodiments, the pump assembly may be in series communication with the heat exchangers of the heat exchange assemblies.

As shown in FIG. 4, in this embodiment, the heat dissipation module 30 may further include two pressure sensors 35, and the pressure sensors 35 are electrically connected to the controller 317 and are respectively disposed at the sub outlet 3113 and the sub inlet 3114 of the pump assembly 31 for measuring pressures of the working fluid at that positions. As a result, as increasing or decreasing the quantity of the heat exchange assemblies 32, the controller 317 may automatically control the pump unit 312 to adjust a flow rate of the working fluid according to the variation of the difference between the pressures measured by the pressure sensors 35 for allowing the working fluid to flow in a predetermined pressure difference. Note that the pressure sensors 35 are optional components and may be adopted or omitted according to actual requirements.

In this embodiment, the controller 317 may be electrically connected to the fans 325 of the heat exchange assemblies 32 for controlling rotation speeds of the fans 325 according to requirements, thereby adjusting the cooling capability of each heat exchange assembly 32. On the other hand, there are plural fans 325 in each heat exchange assembly 32, such that when one of the fans 325 is in malfunction, others of the fans 325 can operate for maintaining the cooling capacity of each heat exchange assembly 32. Note that the quantity of the fans 325 may be modified as required.

According to the server system and the heat dissipation module as discussed in the above embodiment, the servers and the heat exchange assemblies are accommodated in the rack and communicate with the pump assembly, and thus when the server system is moved to a predetermined position of a server room, pipes for connecting with the servers, the heat exchange assemblies and the pump assembly can be pre-installed. As a result, after the server system is placed in the predetermined position of the server room, there is no need to assign maintenance personnel to connect those pipes with the servers, the heat exchange assemblies and the pump assembly, thereby saving the arrangement of manpower. In addition, the heat exchange assemblies, the pump assembly and the servers are accommodated in the same rack, which facilitates the server system to be placed in a confined space of the server room, thereby improving space utilization in the server room.

Furthermore, the heat exchange assemblies and the pump assembly are accommodated in the rack instead of a rear side of the rack, which prevents the space occupied by the server system from increasing, and prevents maintenance personnel from maintaining the server system at the rear side of the rack having a higher ambient temperature.

On the other hand, the heat exchange assemblies are modularized and removable, which can prevent the cooling capability of the heat exchange assemblies from being insufficient to the heat dissipation requirement of the servers, or from overly exceeding the heat dissipation requirement of the servers to waste energy.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A server system, comprising:
a rack;
a plurality of servers, disposed in the rack and each having an inlet and an outlet; and
a heat dissipation module, comprising:
a pump assembly, disposed in the rack and having a main inlet, a sub inlet, a main outlet and a sub outlet;
a main manifold assembly, comprising a first main pipeline and a second main pipeline, wherein the first main pipeline is connected to the main outlet of the pump assembly and the inlet of each of the plurality of servers, and the second main pipeline is connected to the outlet of each of the plurality of servers and the main inlet of the pump assembly;
a plurality of heat exchange assemblies, removably disposed in the rack and each having an inlet and an outlet; and
a sub manifold assembly, comprising a first sub pipeline and a second sub pipeline, wherein the first sub pipeline is connected to the sub outlet of the pump assembly and the inlet of each of the plurality of heat exchange assemblies, and the second sub pipeline is connected to the outlet of each of the plurality of heat exchange assemblies and the sub inlet of the pump assembly.

2. The server system according to claim 1, wherein the rack has an accommodation space and an inner bottom surface, the inner bottom surface is located at a bottom of the accommodation space, the plurality of servers, the pump assembly and the plurality of heat exchange assemblies are located in the accommodation space, and heights of the plurality of servers, the pump assembly and the plurality of heat exchange assemblies relative to the inner bottom surface are different from one another.

3. The server system according to claim 2, wherein the plurality of heat exchange assemblies are located between the plurality of servers and the pump assembly.

4. The server system according to claim 3, wherein the pump assembly is located closer to the inner bottom surface than the plurality of heat exchange assemblies and the plurality of servers.

5. The server system according to claim 1, wherein the heat dissipation module further comprises two pressure sensors, and the two pressure sensors are respectively disposed at the sub outlet and the sub inlet of the pump assembly.

6. The server system according to claim 1, wherein each of the plurality of heat exchange assemblies comprises a casing, a heat exchanger and a plurality of fans; in each of the plurality of heat exchange assemblies, the heat exchanger and the plurality of fans are located in the casing, the inlet and the outlet are located at one side of the heat exchanger, and the plurality of fans are located at another side of the heat exchanger located opposite to the inlet and the outlet.

7. The server system according to claim 6, wherein the heat exchanger is a radiator, and the heat exchanger has a height substantially equal to a 4 U server.

8. The server system according to claim 1, further comprising a plurality of rail assemblies, wherein the plurality of heat exchange assemblies are removably disposed in the rack via the plurality of rail assemblies.

9. The server system according to claim 1, wherein the pump assembly comprises a casing and at least two pump units, the at least two pump units are removably disposed in the casing.

10. A heat dissipation module, comprising:
a pump assembly, having a sub inlet and a sub outlet;
a plurality of heat exchange assemblies, each having an inlet and an outlet; and
a sub manifold assembly, comprising a first sub pipeline and a second sub pipeline, wherein the first sub pipeline is connected to the sub outlet of the pump assembly and the inlet of each of the plurality of heat exchange assemblies, and the second sub pipeline is connected to the outlet of each of the plurality of heat exchange assemblies and the sub inlet of the pump assembly.

11. The heat dissipation module according to claim 10, wherein each of the plurality of heat exchange assemblies comprises a casing, a heat exchanger and a plurality of fans; in each of the plurality of heat exchange assemblies, the heat exchanger and the plurality of fans are located in the casing, the inlet and the outlet are located at one side of the heat exchanger, and the plurality of fans are located at another side of the heat exchanger located opposite to the inlet and the outlet.

12. The heat dissipation module according to claim 11, wherein the heat exchanger is a radiator.

13. The heat dissipation module according to claim 11, wherein the heat exchanger has a height substantially equal to a 4 U server.

14. The heat dissipation module according to claim 10, further comprising two pressure sensors, wherein the two pressure sensors are respectively disposed at the sub outlet and the sub inlet of the pump assembly.

15. The heat dissipation module according to claim 10, wherein the pump assembly comprises a casing and at least two pump units, and the at least two pump units are removably disposed in the casing.

16. A server system, comprising:
a rack, having an accommodation space and an inner bottom surface located at a bottom of the accommodation space;
a plurality of servers, disposed in the accommodation space; and
a heat dissipation module, comprising:
a pump assembly, disposed in the accommodation space and communicating with the plurality of servers; and
a plurality of heat exchange assemblies, removably disposed in the accommodation space and communicating with the pump assembly;
wherein heights of the plurality of servers, the pump assembly and the plurality of heat exchange assemblies relative to the inner bottom surface are different from one another.

17. The server system according to claim 16, wherein the plurality of heat exchange assemblies are located between the plurality of servers and the pump assembly.

18. The server system according to claim 17, wherein the pump assembly is located closer to the inner bottom surface than the plurality of heat exchange assemblies and the plurality of servers.

19. The server system according to claim 16, wherein each of the plurality of heat exchange assemblies comprises a casing, a heat exchanger and a plurality of fans; in each of the plurality of heat exchange assemblies, the heat exchanger and the plurality of fans are located in the casing, the heat exchanger has an inlet and an outlet which are located at one side of the heat exchanger, and the plurality of fans are located at another side of the heat exchanger located opposite to the inlet and the outlet.

20. The server system according to claim 19, wherein the heat exchanger is a radiator, and the heat exchanger has a height substantially equal to a 4 U server.
